(19) United States
(12) Patent Application Publication
(10) Pub. No.: US 2026/0254469 A1
(43) Pub. Date: Aug. 27, 2026

(54) TRANSMISSION CIRCUIT AND COMMUNICATION DEVICE INCORPORATING THE SAME

(71) Applicant: Murata Manufacturing Co., Ltd., Nagaokakyo-shi (JP)

(72) Inventor: Kenji TAHARA, Nagaokakyo-shi (JP)

(21) Appl. No.: 19/535,264

(22) Filed: Feb. 10, 2026

(30) Foreign Application Priority Data
Feb. 27, 2025 (JP) 2025-029770

(51) Int. Cl. H04B 1/04; H03H 17/08

(52) U.S. Cl. CPC H04B 1/0458; H03H 17/08; H04B 2001/0408

(57) ABSTRACT

A transmission circuit amplifies and transmits high-frequency signals to a planar radiating element having feed points. The transmission circuit includes amplification circuits and phase-shift lines. The amplification circuits supply high-frequency signals to the feed points. The phase-shift line is connected between the amplification circuit and the feed point. The phase-shift line is connected between the amplification circuit and the feed point. The phase-shift line is connected between the amplification circuit and the feed point. The feed points are arranged at positions that are offset from a center of the radiating element in opposite directions from each other along a first direction. The feed points are arranged at positions that are offset from the center of the radiating element in opposite directions from each other along a second direction that intersects the first direction.

### CROSS REFERENCE TO RELATED APPLICATION

This application claims priority from Japanese Patent Application No. 2025-029770, filed on February 27, 2025. The content of these applications are incorporated herein by reference in its entirety.

### BACKGROUND OF THE DISCLOSURE

### Field of the Disclosure

The present disclosure relates to transmission circuits and communication devices incorporating the same, and more specifically to techniques for improving robustness against load variations in transmission circuits having amplifiers.

### Description of the Related Art

Japanese Unexamined Patent Application Publication No. 2024-49977 discloses an amplifier module with a configuration in which a patch antenna has four feed points and a power amplifier is individually connected to each of the four feed points. In the amplifier module disclosed in Japanese Unexamined Patent Application Publication No. 2024-49977, in a case where the patch antenna is viewed in plan view, the four feed points are arranged rotationally symmetrically with respect to the center of the patch antenna. The power amplifier connected to each feed point is a Doherty amplifier. Signals with a 90° phase difference are inputted to two feed points of the patch antenna that are adjacent in the rotational direction.

In the amplifier module disclosed in Japanese Unexamined Patent Application Publication No. 2024-49977, circularly polarized radio waves can be radiated using high-frequency signals supplied to the four feed points, and a predetermined back-off is ensured by implementing each amplifier as a Doherty amplifier so that the efficiency of the amplifier module can be increased.

### BRIEF SUMMARY OF THE DISCLOSURE

In contrast, in the amplifier module disclosed in Japanese Unexamined Patent Application Publication No. 2024-49977, although each power amplifier is implemented as a Doherty amplifier, in a case where the load impedance of the radiating element varies, the impedance of each amplifier included in the amplifier changes. Thus, the output power of each amplifier may vary depending on the phase, and the output power of the power amplifier as a whole may become unstable.

The present disclosure has been made to solve such problems, and a possible benefit thereof is to improve robustness against load variations in a transmission circuit that amplifies and transmits high-frequency signals to a radiating element having four feed points.

A transmission circuit according to the present disclosure amplifies and transmits high-frequency signals to a planar radiating element having first to fourth feed points. The transmission circuit includes first to fourth amplification circuits and first to third phase-shift lines. The first to fourth amplification circuits supply high-frequency signals to the first to fourth feed points, respectively. The first phase-shift line is connected between the second amplification circuit and the second feed point. The second phase-shift line is connected between the third amplification circuit and the third feed point. The third phase-shift line is connected between the fourth amplification circuit and the fourth feed point. The first feed point and the third feed point are arranged at positions that are offset from a center of the radiating element in opposite directions from each other along a first direction. The second feed point and the fourth feed point are arranged at positions that are offset from the center of the radiating element in opposite directions from each other along a second direction that intersects the first direction. In a case where a wavelength of high-frequency signals supplied to the radiating element is λ, the first phase-shift line has a line length of λ/8, the second phase-shift line has a line length of λ/4, and the third phase-shift line has a line length of (3/8)λ.

In a transmission circuit according to the present disclosure, phase-shift lines with line lengths differing by λ/8 are arranged along the lines from each amplification circuit to its corresponding feed point. This allows output power variations of each amplification circuit to be shifted by 90° in phase when load impedance variations occur. This allows output power variations in response to load variations to be suppressed over the entire phase range. Furthermore, at any phase, the output power of at least one of the amplification circuits can be made higher than the average power. Thus, the robustness against load variations can be improved in the transmission circuit that amplifies and transmits high-frequency signals to the radiating element having four feed points.

### BRIEF DESCRIPTION OF THE SEVERAL VIEWS OF THE DRAWINGS

FIG. 1 is a schematic diagram of the configuration of a communication device to which a transmission circuit according to an embodiment is applied;

FIG. 2 is a diagram illustrating the detailed configuration of a power amplification circuit in FIG. 1;

FIG. 3 is a diagram for describing a power amplification circuit according to a comparative example;

FIG. 4 is a diagram for describing characteristics of the power amplification circuit according to the embodiment;

FIG. 5 is a diagram for describing the output state of each amplifier at maximum power;

FIG. 6 is a diagram for describing the output state of each amplifier in the case of a 6-dB back-off;

FIG. 7 is a diagram for describing the output state of each amplifier in the case of a 12-dBback-off;

FIG. 8 is a diagram for describing the output state of each amplifier in the case of an 18-dBback-off; and

FIG. 9 is a diagram illustrating the detailed configuration of a power amplification circuit in a transmission circuit according to a modification.

### DETAILED DESCRIPTION OF THE DISCLOSURE

The following is a detailed description of embodiments of the present disclosure with reference to the drawings. Note that the same or equivalent portions in the drawings are marked with the same symbols and their descriptions are not repeated.

### Embodiment

### Overall Configuration of Communication Device

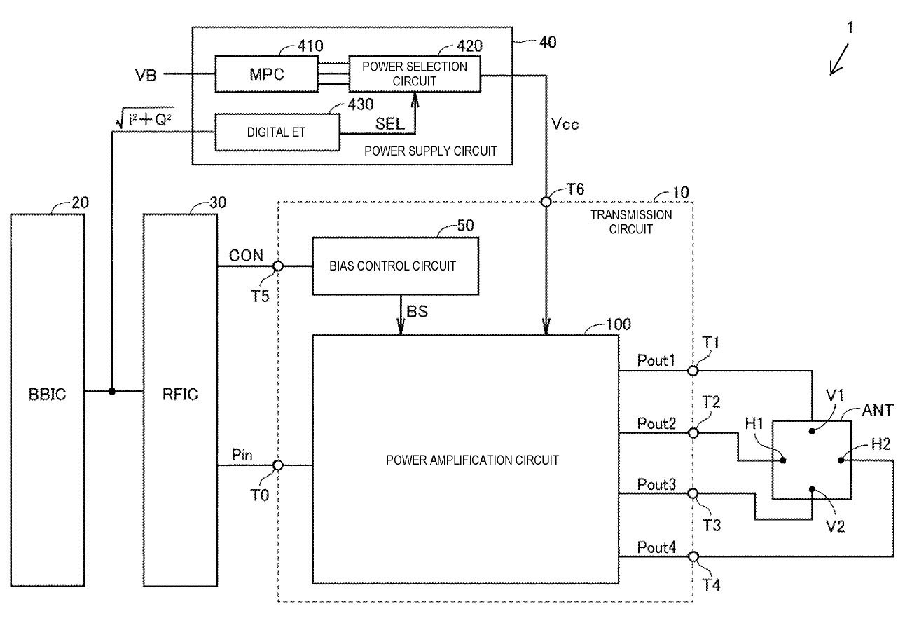

FIG. 1 is a schematic diagram of the configuration of a communication device 1 to which a transmission circuit 10 according to an embodiment is applied. The communication device 1 is, for example, a portable terminal, a personal computer with communication functions, or a base station for portable terminals. Examples of the portable terminal include a cellular phone, a smartphone, and a tablet.

Referring to FIG. 1, the communication device 1 includes a radiating element ANT, the transmission circuit 10, a baseband integrated circuit (BBIC) 20, a radio frequency integrated circuit (RFIC) 30, and a power supply circuit 40. The BBIC 20 is included in a baseband signal processing circuit. The transmission circuit 10 includes input terminals T0, T5, and T6, output terminals T1 to T4, a bias control circuit 50, and a power amplification circuit 100. In summary, in the communication device 1, the RFIC 30 up-converts an intermediate frequency (IF) signal transferred from the BBIC 20 into a high-frequency (radio frequency (RF)) signal, the power amplification circuit 100 amplifies the high-frequency signal, and the resulting signal is radiated from the radiating element ANT.

The RFIC 30 is an example of a signal processing circuit that processes high-frequency signals. The RFIC 30 up-converts an intermediate frequency signal transferred from the BBIC 20 into a high-frequency signal, and outputs the generated high-frequency signal to the transmission circuit 10 via the input terminal T0.

The power supply circuit 40 is an example of a so-called digital tracker and can supply a power supply voltage Vcc at several different voltage levels to the power amplification circuit 100. The power supply circuit 40 includes a multilevel power converter (MPC) 410, a power selection circuit 420, and digital envelope tracker (digital ET) 430.

The MPC 410 includes multiple DC/DC converters, which are not illustrated in FIG. 1. The MPC 410 converts the battery voltage VB supplied from an external battery into multiple different voltage levels and supplies the voltage levels to the power selection circuit 420.

The digital ET 430 receives the I and Q waveform signals of a transmission signal from the BBIC 20 and tracks the envelope of the transmission signal in a digital ET mode. The digital ET 430 generates a selection signal SEL in response to the voltage level of the envelope of the transmission signal and outputs the selection signal SEL to the power selection circuit 420.

The power selection circuit 420 selects the voltage corresponding to the selection signal SEL from among the multiple voltage levels supplied from the MPC 410 and supplies the selected voltage as the power supply voltage Vcc to the power amplification circuit 100 via the input terminal T6.

The bias control circuit 50 receives a control signal CON received from the RFIC 30 via the input terminal T5. The bias control circuit 50 generates, based on the control signal CON, a bias signal BS for controlling the magnitude and supply timing of a bias current for amplifiers included in the power amplification circuit 100, and outputs the bias signal BS to the power amplification circuit 100.

The power amplification circuit 100 amplifies an input signal Pin received from the RFIC 30 via the input terminal T0 to generate four output signals Pout1 to Pout4.

The radiating element ANT is, for example, a planar patch antenna with a square shape. The radiating element ANT radiates the output signals Pout1 to Pout4, which are high-frequency signals outputted from the transmission circuit 10, as radio waves. Note that the shape of the radiating element ANT is not limited to a square shape and may be circular or have any other polygonal shape.

The output terminal T1 of the transmission circuit 10 is connected to a feed point V1 of the radiating element ANT. The output terminal T2 of the transmission circuit 10 is connected to a feed point H1 of the radiating element ANT. The output terminal T3 of the transmission circuit 10 is connected to a feed point V2 of the radiating element ANT. The output terminal T4 of the transmission circuit 10 is connected to a feed point H2 of the radiating element ANT.

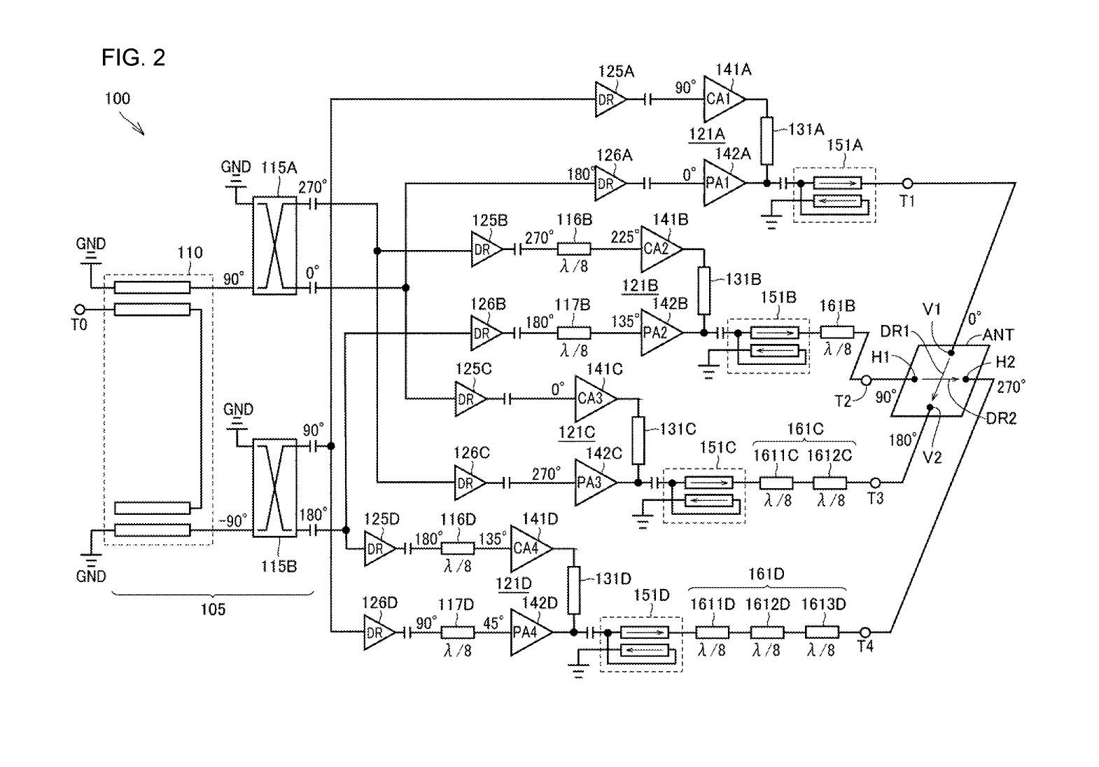

The feed points V1 and V2 are arranged at positions that are offset from the center of the radiating element ANT in opposite directions from each other along a direction DR1 (a first direction) in FIG. 2. The feed points H1 and H2 are arranged at positions that are offset from the center of the radiating element ANT in opposite directions from each other along a direction DR2 (a second direction) that intersects the direction DR1.

Note that the directions DR1 and DR2 are orthogonal to each other in the radiating element ANT in the embodiment. In the following description, the direction DR1 may be referred to as the vertical direction and the direction DR2 as the horizontal direction.

### Detailed Configuration of Power Amplification Circuit

FIG. 2 is used to describe the detailed configuration of the power amplification circuit 100 in the transmission circuit 10.

The power amplification circuit 100 includes a splitting circuit 105, driver amplifiers 125A to 125D and 126A to 126D, amplification circuits 121A to 121D, phase-shift lines 116B, 116D, 117B, 117D, and 161B to 161D.

The splitting circuit 105 includes a balun 110 and hybrid couplers 115A and 115B. The balun 110 includes an unbalanced terminal and two balanced terminals, and splits a high-frequency signal received through the unbalanced terminal into two paths and provides a 180° phase difference between the two split signals.

The balun 110 is, for example, a Marchand balun having a λ/2 line connected to the unbalanced terminal and two λ/4 lines connected to the two balanced terminals in a respective manner, in a case where the wavelength of a high-frequency signal to be transmitted is λ. The path (a first path) from one of the balanced terminals (a first balanced terminal) is connected to the hybrid coupler 115A, and the path (a second path) from the other balanced terminal (a second balanced terminal) is connected to the hybrid coupler 115B.

The first path branched from the balun 110 is connected to one input terminal of the hybrid coupler 115A. A ground potential GND is connected to the other input terminal of the hybrid coupler 115A. The hybrid coupler 115A further splits the signal from the balun 110 into two paths and provides a 90° phase difference between the two split signals.

Similarly, the second path branched from the balun 110 is connected to one input terminal of the hybrid coupler 115B. The ground potential GND is connected to the other input terminal of the hybrid coupler 115B. The hybrid coupler 115B further splits the signal from the balun 110 into two paths and provides a 90° phase difference between the two split signals.

The amplification circuits 121A to 121D amplify high-frequency signals supplied from the hybrid couplers 115A and 115B. The amplification circuits 121A to 121D supply the amplified high-frequency signals to their corresponding feed points of the radiating element ANT via the output terminals T1 to T4, respectively.

Each of the amplification circuits 121A to 121D is a so-called Doherty amplifier, which has a carrier amplifier, a peaking amplifier, a phase-shift line having a line length of λ/4, and an impedance transformer.

Specifically, the amplification circuit 121A includes a carrier amplifier 141A, a peaking amplifier 142A, a phase-shift line 131A, and an impedance transformer 151A. The phase-shift line 131A is connected between the output end of the carrier amplifier 141A and the output end of the peaking amplifier 142A. The output end of the peaking amplifier 142A is connected to the output terminal T1 with the impedance transformer 151A interposed therebetween.

The amplification circuit 121B includes a carrier amplifier 141B, a peaking amplifier 142B, a phase-shift line 131B, and an impedance transformer 151B. The phase-shift line 131B is connected between the output end of the carrier amplifier 141B and the output end of the peaking amplifier 142B. The output end of the peaking amplifier 142B is connected to the output terminal T2 with the impedance transformer 151B and the phase-shift line 161B having a line length of λ/8 interposed therebetween.

The amplification circuit 121C includes a carrier amplifier 141C, a peaking amplifier 142C, a phase-shift line 131C, and an impedance transformer 151C. The phase-shift line 131C is connected between the output end of the carrier amplifier 141C and the output end of the peaking amplifier 142C. The output end of the peaking amplifier 142C is connected to the output terminal T3 with the impedance transformer 151C and the phase-shift line 161C interposed therebetween.

The phase-shift line 161C includes lines 1611C and 1612C, which are connected in series. Each of the lines 1611C and 1612C has a line length of λ/8. That is, the phase-shift line 161C has a line length of λ/4.

The amplification circuit 121D includes a carrier amplifier 141D, a peaking amplifier 142D, a phase-shift line 131D, and an impedance transformer 151D. The phase-shift line 131D is connected between the output end of the carrier amplifier 141D and the output end of the peaking amplifier 142D. The output end of the peaking amplifier 142D is connected to the output terminal T4 with the impedance transformer 151D and the phase-shift line 161D interposed therebetween.

The phase-shift line 161D includes lines 1611D, 1612D, and 1613D, which are connected in series. Each of the lines 1611D, 1612D, and 1613D has a line length of λ/8. That is, the phase-shift line 161D has a line length of (3/8)λ.

In each of the amplification circuits 121A to 121D, the signal outputted from the carrier amplifier and the signal outputted from the peaking amplifier are current-combined.

One of the output terminals of the hybrid coupler 115A (a first output terminal) is connected to the carrier amplifier 141B of the amplification circuit 121B with the driver amplifier 125B and the phase-shift line 116B interposed therebetween, and is also connected to the peaking amplifier 142C of the amplification circuit 121C with the driver amplifier 126C interposed therebetween.

The other output terminal of the hybrid coupler 115A (a second output terminal) is connected to the peaking amplifier 142A of the amplification circuit 121A with the driver amplifier 126A interposed therebetween, and is also connected to the carrier amplifier 141C of the amplification circuit 121C with the driver amplifier 125C interposed therebetween.

One of the output terminals of the hybrid coupler 115B (a third output terminal) is connected to the carrier amplifier 141A of the amplification circuit 121A with the driver amplifier 125A interposed therebetween, and is also connected to the peaking amplifier 142D of the amplification circuit 121D with the driver amplifier 126D and the phase-shift line 117D interposed therebetween.

The other output terminal of the hybrid coupler 115B (a fourth output terminal) is connected to the peaking amplifier 142B of the amplification circuit 121B with the driver amplifier 126B and the phase-shift line 117B interposed therebetween, and is also connected to the carrier amplifier 141D of the amplification circuit 121D with the driver amplifier 125D and the phase-shift line 116D interposed therebetween.

The impedance transformer included in each amplification circuit includes a main line and a sub-line and transforms the impedance at a predetermined transformation ratio. The main line and sub-line have, for example, a line length of λ/8 or λ/16. One end of the main line is connected to the output end of the corresponding peaking amplifier, and the other end is connected to the corresponding output terminal. Note that the impedance transformers 151B to 151D are connected to the corresponding output terminals T2 to T4 with the phase-shift lines 161B to 161D interposed therebetween, respectively. One end of the sub-line is connected to the one end of the main line, and the other end is connected to the ground potential GND.

Next, the phases of signals at various locations of the power amplification circuit 100 will be described. Suppose that a signal supplied from the balun 110 to the hybrid coupler 115A has a phase of 90° and a signal supplied to the hybrid coupler 115B has a phase of -90°.

In this case, a signal with a phase of 270° is outputted from the one output terminal of the hybrid coupler 115A (the first output terminal), and a signal with a phase of 0° is outputted from the other output terminal (the second output terminal). A signal with a phase of 90° is outputted from the one output terminal of the hybrid coupler 115B (the third output terminal), and a signal with a phase of 180° is outputted from the other output terminal (the fourth output terminal).

In the amplification circuit 121A, the phase inputted to the carrier amplifier 141A is 90°, and the phase inputted to the peaking amplifier 142A is 0°. Thus, a signal with a phase of 0° is supplied to the feed point V1 of the radiating element ANT.

In the amplification circuit 121B, the signals from each hybrid coupler are phase-delayed by 45° by the phase-shift lines 116B and 117B, which have a line length of λ/8. Thus, the phase inputted to the carrier amplifier 141B is 225°, and the phase inputted to the peaking amplifier 142B is 135°. The signal outputted from the amplification circuit 121B has a phase of 135°, but the phase is further delayed by 45° by the phase-shift line 161B having a line length of λ/8, thereby supplying a signal with a phase of 90° to the feed point H1 of the radiating element ANT.

In the amplification circuit 121C, the phase inputted to the carrier amplifier 141C is 0°, and the phase inputted to the peaking amplifier 142C is 270°. The signal outputted from the amplification circuit 121C has a phase of 270°, but the phase is delayed by 90° by the phase-shift line 161C having a line length of λ/4, thereby supplying a signal with a phase of 180° to the feed point V2 of the radiating element ANT.

In the amplification circuit 121D, the signals from each hybrid coupler are phase-delayed by 45° by the phase-shift lines 116D and 117D, which have a line length of λ/8. Thus, the phase inputted to the carrier amplifier 141D is 135°, and the phase inputted to the peaking amplifier 142D is 45°. The signal outputted from the amplification circuit 121D has a phase of 45°, but the phase is further delayed by 135° by the phase-shift line 161D having a line length of (3/8)λ, thereby supplying a signal with a phase of -90° (i.e., 270°) to the feed point H1 of the radiating element ANT.

That is, the four feed points of the radiating element ANT are supplied with signals that are phase-shifted by 90° in the rotational direction with respect to the center of the radiating element ANT. With this configuration, the signals supplied to the four feed points are combined at the radiating element ANT.

### Phase-Shift Lines Between Amplification Circuits and Radiating Element

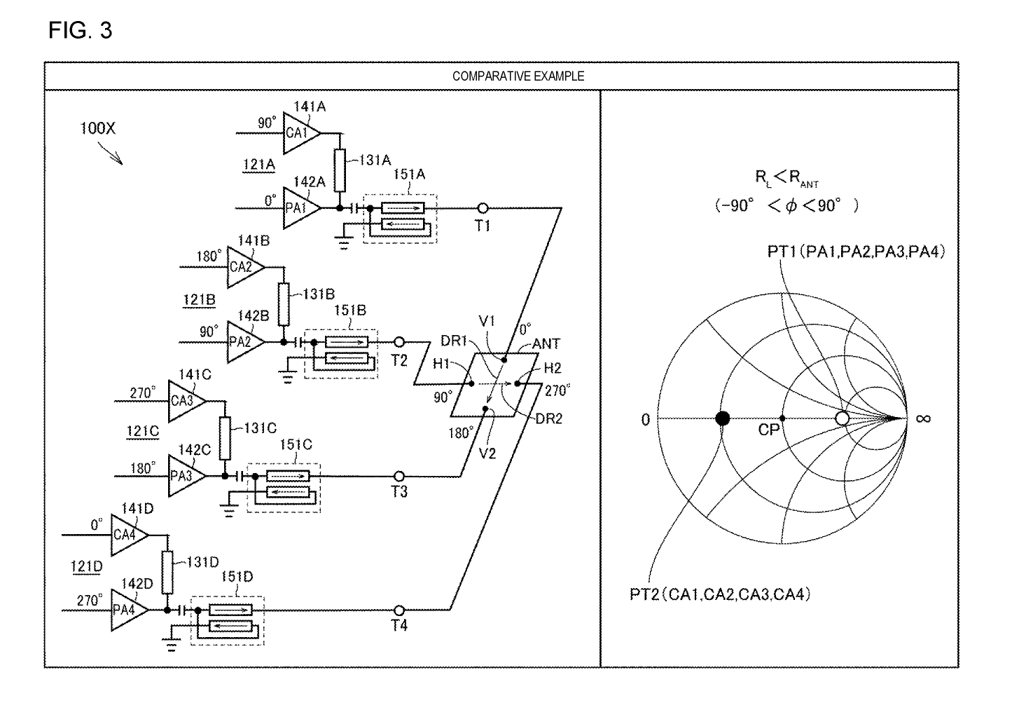

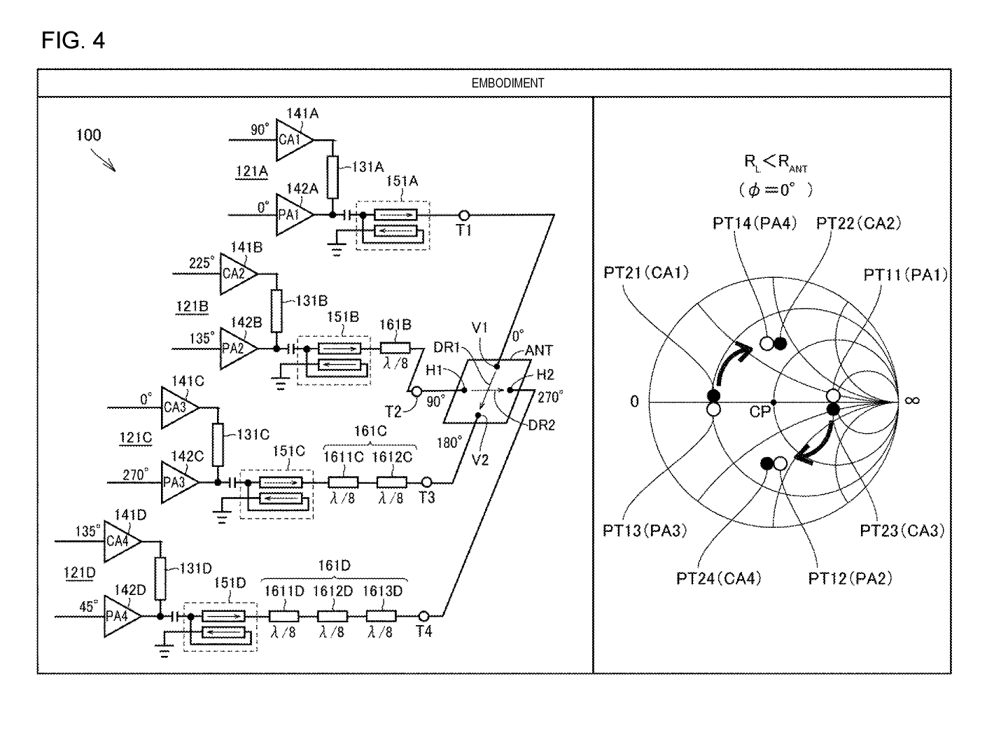

Next, FIGS. 3 and 4 are used to describe the roles of the phase-shift lines 161B, 161C, and 161D arranged between the amplification circuits 121B, 121C, and 121D and the radiating element ANT. Note that FIGS. 3 and 4 illustrate, as an example, a case where all the amplifiers of each amplification circuit are driven.

FIG. 3 illustrates a power amplification circuit 100X according to a comparative example in which the phase-shift lines 161B, 161C, and 161D are not arranged. The left side of FIG. 3 illustrates a schematic configuration of the power amplification circuit 100X. The right side of FIG. 3 illustrates the position of each amplifier on the Smith chart in the region where a load impedance R_{ANT} of the radiating element ANT is greater than a characteristic impedance R_{L}.

The left side of FIG. 4 illustrates a schematic configuration of the power amplification circuit 100 according to the embodiment. The right side of FIG. 4 illustrates the position of each amplifier on the Smith chart for a phase φ of 0°.

In a Doherty amplifier such as that used in the power amplification circuit 100 according to the embodiment, the output end of the carrier amplifier is connected to the output end of the amplification circuit (i.e., the output end of the peaking amplifier) with a phase-shift line having a line length of λ/4 interposed therebetween. Thus, the phase difference between the load impedance of the carrier amplifier and the load impedance of the peaking amplifier is 180°.

Thus, for example, when the load impedance of the carrier amplifier is high, the load impedance of the peaking amplifier is low. In contrast, when the load impedance of the carrier amplifier is low, the load impedance of the peaking amplifier is high.

In amplifiers, the output power generally decreases as the load impedance increases, and increases as the load impedance decreases. As described above, the load-impedance behaviors of the carrier amplifier and the peaking amplifier are opposite in Doherty amplifiers. Thus, when the load impedance R_{ANT} of the radiating element ANT is greater than the characteristic impedance R_{L} (R_{L} < R_{ANT}) due to load variations, the output power of the peaking amplifier decreases and that of the carrier amplifier increases. In contrast, when the load impedance R_{ANT} of the radiating element is smaller than the characteristic impedance R_{L} (R_{L} > R_{ANT}), the output power of the peaking amplifier increases and that of the carrier amplifier decreases.

With a configuration where high-frequency signals are supplied from Doherty amplifiers to the four respective feed points of the radiating element ANT, in a case where the output end of each amplification circuit is directly connected to the corresponding feed point as in the power amplification circuit 100X according to the comparative example illustrated on the left side of FIG. 3, the output power of the peaking amplifier of each amplification circuit decreases and that of the carrier amplifier increases in the phase range (-90° < φ < 90°) where the load impedance R_{ANT} of the radiating element ANT is greater than the characteristic impedance R_{L} (R_{L} < R_{ANT}).

The Smith chart on the right side of FIG. 3 illustrates this state. For example, all carrier amplifiers are located at a point PT2 to the left of a center CP of the Smith chart, while all peaking amplifiers are located at a point PT1 to the right of the center CP of the Smith chart. The point PT1 is the position where the output power is at a minimum, and the point PT2 is the position where the output power is at a maximum.

In this state, the power variations are canceled out in each amplification circuit by a decrease in the output power of the peaking amplifier and an increase in the output power of the carrier amplifier. High-frequency signals with opposite phases to each other are supplied to the feed points V1 and V2 from the amplification circuits 121A and 121C. Thus, for radio waves with a direction DR1 as a polarization direction (vertical polarization), the power variations of the amplification circuit 121A and those of the amplification circuit 121C cancel each other out.

Similarly, high-frequency signals with opposite phases to each other are supplied to the feed points H1 and H2 from the amplification circuits 121B and 121D. Thus, for radio waves with a direction DR2 as a polarization direction (horizontal polarization), the power variations of the amplification circuit 121B and those of the amplification circuit 121D cancel each other out. As a result, the average power outputted from the power amplification circuit 100X exhibits a flat characteristic with respect to phase and over the entire range.

However, when load variations occur and the phase φ changes from this state and reaches a point (φ = 90°, 270°) where the magnitude relationship between the load impedance R_{ANT} of the radiating element ANT and the characteristic impedance R_{L} switches, both the output power of the peaking amplifier and that of the carrier amplifier reach the average power level. Thus, the power variations decrease; however, all the amplifiers will enter a state in which a large amount of power cannot be produced.

In contrast, in the power amplification circuit 100 according to the embodiment illustrated in FIG. 4, the amplification circuit 121B is connected to the radiating element ANT with the phase-shift line 161B having a line length of λ/8 interposed therebetween. The amplification circuit 121C is connected to the radiating element ANT with the phase-shift line 161B having a line length of λ/4 interposed therebetween. The amplification circuit 121D is connected to the radiating element ANT with the phase-shift line 161D having a line length of (3/8)λ interposed therebetween.

These phase-shift lines 161B, 161C, and 161D shift the phase at the output end of the amplification circuit 121B by 45°, that at the amplification circuit 121C by 90°, and that at the amplification circuit 121D by 135°, compared with the case of the comparative example illustrated in FIG. 3.

As illustrated on the right side of FIG. 4, for example, in the case of the phase φ = 0° in the region where the load impedance R_{ANT} of the radiating element ANT is greater than the characteristic impedance R_{L} (R_{L} < R_{ANT}), the peaking amplifier 142A of the amplification circuit 121A and the carrier amplifier 141C of the amplification circuit 121C are located at points PT11 and PT23, respectively, to the right of the center CP of the Smith chart, and the carrier amplifier 141A of the amplification circuit 121A and the peaking amplifier 142C of the amplification circuit 121C are located at points PT21 and PT13, respectively, to the left of the center CP of the Smith chart.

The carrier amplifier 141B of the amplification circuit 121B and the peaking amplifier 142D of the amplification circuit 121D are located at points PT22 and PT14, respectively, above the center CP. The peaking amplifier 142B of the amplification circuit 121B and the carrier amplifier 141D of the amplification circuit 121D are located at points PT12 and PT24, respectively, below the center CP.

In this case, when the phase φ varies due to load variations, the points indicating the respective amplifiers rotate around the center CP on the Smith chart. Then, no matter how the phase φ changes due to load variations, at least two amplifiers are located in the region to the left of the center CP on the Smith chart, that is, the region that outputs more power than the average power. As a result, in the power amplification circuit 100 according to the embodiment, the power variations in response to load variations can be suppressed over the entire phase range. In addition, the output power of at least one of the amplifiers can be maintained higher than the average power at any phase. The robustness against load variations can therefore be further improved.

### Operation of Power Amplification Circuit

In the power amplification circuit 100, since each amplification circuit is implemented as a Doherty amplifier, the efficiency of the power amplification circuit 100 can be improved by switching among the amplifiers used, in response to the power level of the input signal Pin.

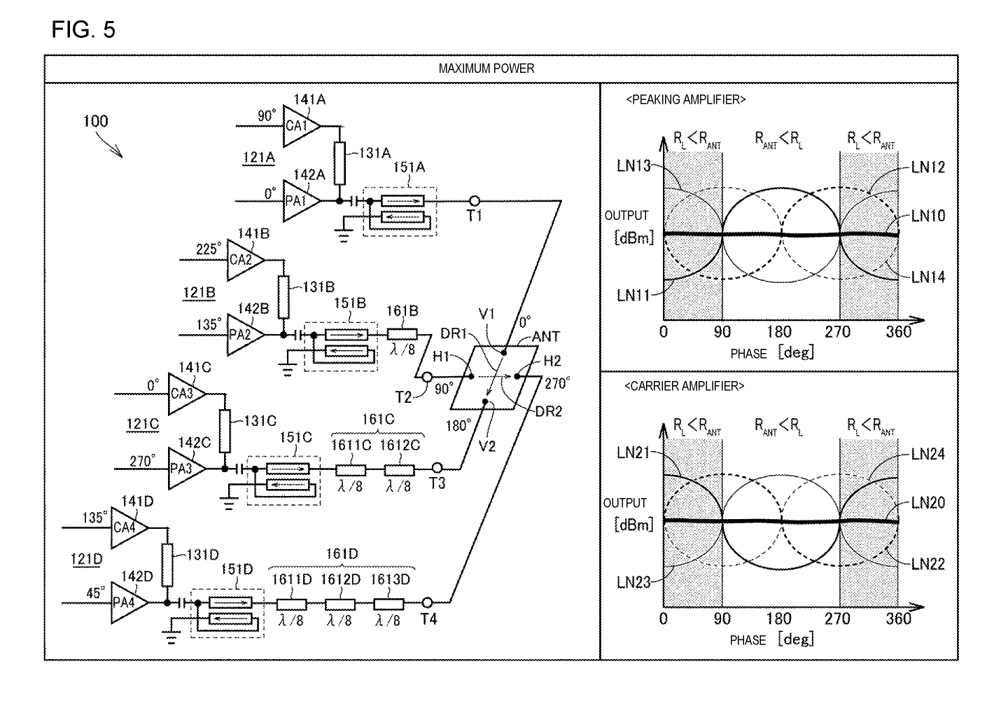

In the following, FIGS. 5 to 8 are used to describe the relationship between output power and efficiency associated with amplifier switching in each amplification circuit.

### At Maximum Power

FIG. 5 is a diagram for describing the output state of each amplifier in a case where the power level of the input signal Pin is at a maximum. The left side of FIG. 5 illustrates the operating state of each amplifier. The right side of FIG. 5 illustrates graphs of output power variations in response to load variations for the peaking amplifier (top) and carrier amplifier (bottom) of each amplification circuit.

On the top graph on the right side, a solid line LN11 indicates the output power of the peaking amplifier 142A of the amplification circuit 121A, and a broken line LN12 indicates the output power of the peaking amplifier 142B of the amplification circuit 121B. A solid line LN13 indicates the output power of the peaking amplifier 142C of the amplification circuit 121C, and a broken line LN14 indicates the output power of the peaking amplifier 142D of the amplification circuit 121D.

On the bottom graph on the right side, a solid line LN21 indicates the output power of the carrier amplifier 141A of the amplification circuit 121A, and a broken line LN22 indicates the output power of the carrier amplifier 141B of the amplification circuit 121B. A solid line LN23 indicates the output power of the carrier amplifier 141C of the amplification circuit 121C, and a broken line LN24 indicates the output power of the carrier amplifier 141D of the amplification circuit 121D.

Solid lines LN10 and LN20 indicate output powers combined at the radiating element ANT. With reference to FIG. 5, in the case of maximum output power, both the peaking amplifier and the carrier amplifier are in operation in any of the amplification circuits 121A to 121D.

First, the amplification circuits 121A and 121C for radiating vertically polarized radio waves will be described. On the right graph, in a case where the load impedance R_{ANT} of the radiating element ANT is greater than the characteristic impedance R_{L} (R_{L} < R_{ANT}), that is, a case where the phase of the load impedance is between 0° and 90° or between 270° and 360°, the load impedance seen from the peaking amplifier 142A of the amplification circuit 121A increases, and thus the output power of the peaking amplifier 142A decreases (the line LN11). In contrast, for the carrier amplifier 141A, since the signal is routed through the phase-shift line 131A, the load impedance seen from the carrier amplifier 141A decreases, and thus the output power of the carrier amplifier 141A increases (the line LN21).

For the amplification circuit 121C, in a case where the phase is between 0° and 90° or between 270° and 360°, the signal is routed through the phase-shift line 161C having a line length of λ/4, the load impedance seen from the peaking amplifier 142C decreases. As a result, the output power of the peaking amplifier 142C increases due to the decrease in load (the line LN13). In contrast, for the carrier amplifier 141C, since the load impedance seen from the carrier amplifier 141C increases due to the phase-shift line 131C, the output power of the carrier amplifier 141C decreases (the line LN23).

Thus, the power variations are canceled out by the decreases in the output powers of the peaking amplifier 142A and carrier amplifier 141C and the increases in the output powers of the carrier amplifier 141A and peaking amplifier 142C.

For the amplification circuits 121A and 121C, in a case where the load impedance R_{ANT} is smaller than the characteristic impedance R_{L} (R_{ANT} < R_{L}), that is, a case where the phase of the load impedance is between 90° and 270°, the load impedance seen from the peaking amplifier 142A of the amplification circuit 121A decreases, and thus the output power of the peaking amplifier 142A increases (the line LN11). In contrast, for the carrier amplifier 141A, since the signal is routed through the phase-shift line 131A, the load impedance seen from the carrier amplifier 141A increases, and the output power of the carrier amplifier 141A decreases (the line LN21).

For the amplification circuit 121C, in a case where the phase is between 90° and 270°, since the signal is routed through the phase-shift line 161C having a line length of λ/4, the load impedance seen from the peaking amplifier 142C increases. As a result, the output power of the peaking amplifier 142C decreases due to the decrease in load (the line LN13). In contrast, for the carrier amplifier 141C, since the load impedance seen from the carrier amplifier 141C decreases due to the phase-shift line 131C, the output power of the carrier amplifier 141C increases (the line LN23).

Thus, the power variations are canceled out by the increases in the output powers of the peaking amplifier 142A and carrier amplifier 141C and the decreases in the output powers of the carrier amplifier 141A and peaking amplifier 142C.

Next, the amplification circuits 121B and 121D for radiating horizontally polarized radio waves will be described. Since the amplification circuit 121B is connected to the radiating element ANT with the phase-shift line 161B having a line length of λ/8 interposed therebetween, the load impedance seen from the peaking amplifier 142B of the amplification circuit 121B changes by 90° in phase, compared with the load impedance seen from the peaking amplifier 142A of the amplification circuit 121A.

Thus, the load impedance seen from the amplification circuit 121B increases in a case where the phase is between 0° and 180° and decreases in a case where the phase is between 180° and 360°. As a result, the output power of the peaking amplifier 142B decreases in a case where the phase is between 0° and 180° and increases in a case where the phase is between 180° and 360° (the line LN12).

In contrast, since the signal is routed through the phase-shift line 131B, the load impedance seen from the carrier amplifier 141B decreases in a case where the phase is between 0° and 180° and increases in a case where the phase is between 180° and 360°. Thus, the output power of the carrier amplifier 141B increases in a case where the phase is between 0° and 180° and decreases in a case where the phase is between 180° and 360° (the line LN22).

The amplification circuit 121D is connected to the radiating element ANT with the phase-shift line 161D having a line length of (3/8)λ interposed therebetween, and the line length of the amplification circuit 121D is longer than that of the amplification circuit 121B by λ/4. Thus, the change in load impedance when seen from the amplification circuit 121D is the opposite of the change in load impedance when seen from the amplification circuit 121B.

Thus, the load impedance seen from the amplification circuit 121D decreases in a case where the phase is between 0° and 180° and increases in a case where the phase is between 180° and 360°. As a result, the output power of the peaking amplifier 142D increases in a case where the phase is between 0° and 180° and decreases in a case where the phase is between 180° and 360° (the line LN14).

In contrast, since the signal is routed through the phase-shift line 131D, the load impedance seen from the carrier amplifier 141D increases in a case where the phase is between 0° and 180° and decreases in a case where the phase is between 180° and 360°. Thus, the output power of the carrier amplifier 141D decreases in a case where the phase is between 0° and 180° and increases in a case where the phase is between 180° and 360° (the line LN24).

Thus, in a case where the phase is between 0° and 180°, the power variations are canceled out by the decreases in the output powers of the peaking amplifier 142B and carrier amplifier 141D and the increases in the output powers of the carrier amplifier 141B and peaking amplifier 142D.

In a case where the phase is between 180° and 360°, the power variations are canceled out by the increases in the output powers of the peaking amplifier 142B and carrier amplifier 141D and the decreases in the output powers of the carrier amplifier 141B and peaking amplifier 142D. This allows power variations in response to load variations to be suppressed over the entire phase range.

Furthermore, at phases of 90° and 270°, the output power of the peaking amplifier or carrier amplifier of each of the amplification circuits 121B and 121D increases at the timing at which the output power of each amplifier of the amplification circuits 121A and 121C switches between increasing and decreasing. At phases of 0° and 180°, the output power of the peaking amplifier or carrier amplifier of each of the amplification circuits 121A and 121C increases at the timing at which the output power of each amplifier of the amplification circuits 121B and 121D switches between increasing and decreasing. As a result, regarding power variations in response to load variations over the entire phase range, the output power of at least one of the amplification circuits can be made higher than the average power. The robustness against load variations can therefore be improved while ensuring the available output power level.

### When Power Level Drops

The following describes the operating state of the power amplification circuit 100 in a case where the power level of the input signal Pin drops from maximum power. Since each amplification circuit of the power amplification circuit 100 is a Doherty amplifier, the load impedance is increased by deactivating the amplifier as appropriate in response to the power level of the input signal Pin, so that the efficiency of the entire power amplification circuit 100 can be improved.

In the embodiment, the power amplification circuit 100 operates by switching among four operation modes in response to the power level of the input signal Pin. The power supply voltage Vcc from the power supply circuit 40 is switched among four stages VC1 to VC4 (VC1 > VC2 > VC3 > VC4) in each operation mode, in response to the power level of the input signal Pin. In a case where the power level of the input signal Pin described above is at maximum power (has a first power value), the power supply voltage Vcc is set to VC1.

### (1) At 6-dB Back-Off

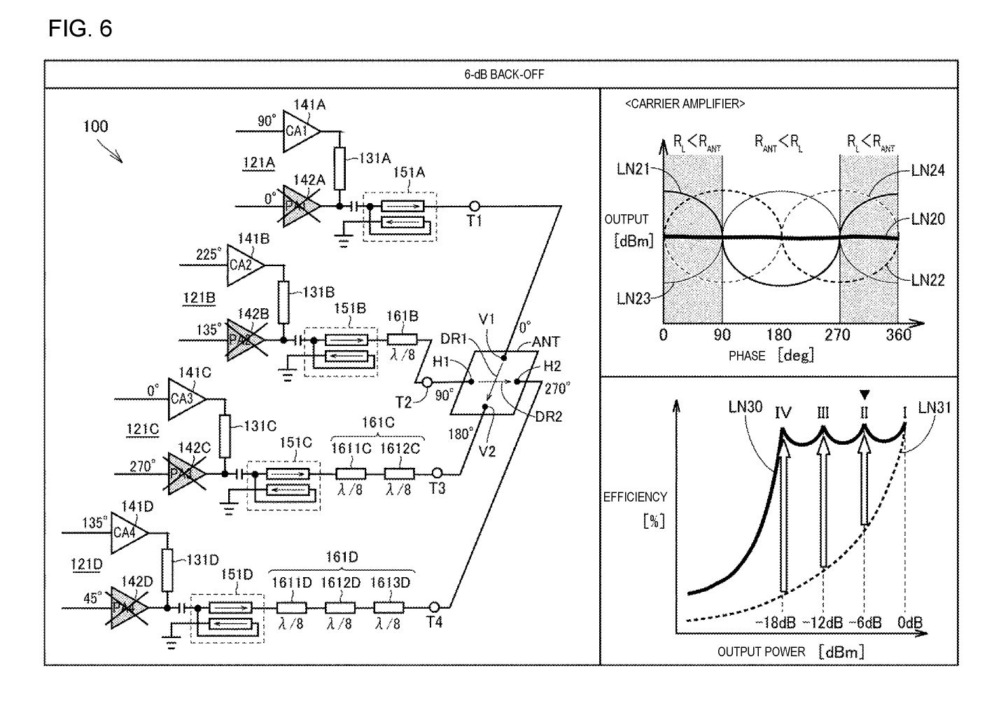

First, FIG. 6 is used to describe the operation mode for a case where the power level of the input signal Pin has a second power value slightly lower than maximum power. In this case, the power supply voltage Vcc is set to VC2.

On the left sides of FIG. 6 and FIGS. 7 and 8 described below, the operating state of each amplifier of the power amplification circuit 100 in each case is illustrated. The top rows of the right sides illustrate graphs of output power variations in response to load variations for the carrier amplifiers. The bottom rows of the right sides illustrate graphs representing the relationship between output power and efficiency due to amplifier switching.

On the graphs illustrated in the bottom rows of the right sides, the horizontal axis represents the power level of the input signal Pin, and the vertical axis represents the efficiency of the power amplification circuit 100. Note that a solid line LN30 indicates the efficiency of the power amplification circuit 100 according to the embodiment, and a broken line LN31 indicates the efficiency of a Class-AB amplifier capable of outputting the same maximum power as the power amplification circuit 100 when the Class-AB amplifier is used alone. On the graph, an operation mode (I) indicates the case of maximum power and an operation mode (II) indicates a case where the power level has the second power value. An operation mode (III) indicates a case where the power level has a third power value that is lower than the second power value, and an operation mode (IV) indicates a case where the power level has a fourth power value that is lower than the third power value.

In the operation mode (II) in FIG. 6, in each amplification circuit, the peaking amplifier is deactivated, and only the carrier amplifier is activated. In this case, the load impedance of each carrier amplifier is doubled, compared with the case of maximum power. This increases the efficiency of the carrier amplifier, and thus a 6-dB back-off can be achieved. The efficiency is improved compared with the case where a Class-AB amplifier is used alone.

Although only the carrier amplifiers are activated in this case, the amplification circuits 121B to 121D are connected to the corresponding feed points of the radiating element ANT with the phase-shift lines 161B to 161D interposed therebetween, respectively. Thus, as illustrated on the graph on the top row of the right side, the power variations of the carrier amplifier 141A and those of the carrier amplifier 141C cancel each other out, and the power variations of the carrier amplifier 141B and those of the carrier amplifier 141D cancel each other out. Thus, even at a 6-dB back-off, power variations in response to load variations can be suppressed over the entire phase range.

Furthermore, the phase-shift lines 161B to 161D cause the output powers of the carrier amplifiers 141B and 141D to be offset by 90° in phase with respect to the output powers of the carrier amplifiers 141A and 141C. As a result, regarding power variations in response to load variations over the entire phase range, the output power of at least one of the amplification circuits can be made higher than the average power. The robustness against load variations can therefore be improved while ensuring the available output power level.

### (2) At 12-dB Back-Off

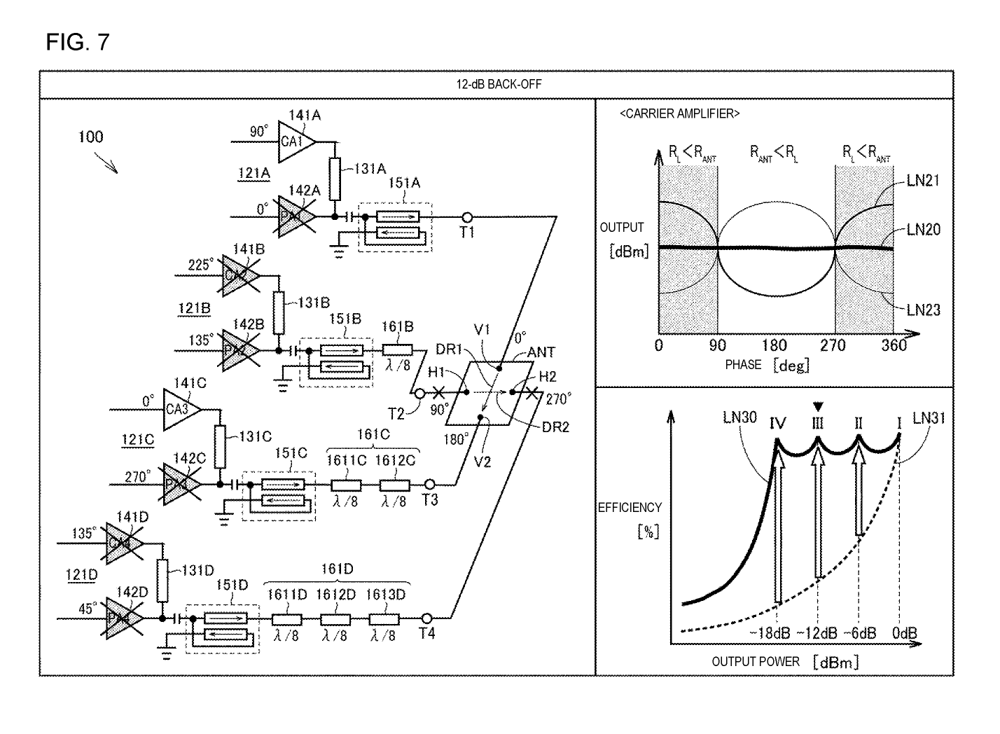

Next, FIG. 7 is used to describe the operation mode (III) for the case of the third power value indicating a lower power level. In this case, the power supply voltage Vcc is set to VC3.

In the operation mode (III) in FIG. 7, the power level is further reduced, so that the carrier amplifier 141B of the amplification circuit 121B and the carrier amplifier 141D of the amplification circuit 121D are further deactivated from the state in FIG. 6. In other words, only the carrier amplifier 141A of the amplification circuit 121A and the carrier amplifier 141C of the amplification circuit 121C are activated. In this case, since no high-frequency signals are supplied to the feed points H1 and H2, only vertically polarized radio waves will be radiated.

In this case, the load impedances of the carrier amplifiers 141A and 141C in operation are further doubled compared with the case in FIG. 6, and are four times higher than in the case of maximum power. This increases the efficiencies of the carrier amplifiers 141A and 141C, resulting in an additional 6-dB back-off. Thus, a 12-dB back-off can be achieved in total.

Even in the operation mode (III) in FIG. 7, the power variations of the carrier amplifier 141A and those of the carrier amplifier 141C cancel each other out, and thus power variations in response to load variations can be suppressed over the entire phase range. Note that since the carrier amplifiers 141B and 141D are deactivated, power greater than the average power cannot be outputted at phases of 90° and 270°. However, the power level is significantly lower in the operation mode (III) than in the operation mode (I) for maximum power, the effect of power variations that occur in certain cases, such as when the phase is 90° or 270°, on the overall characteristics of the power amplification circuit 100 is significantly small. Therefore, this is not a major problem in practical use.

### (3) At 18-dB Back-Off

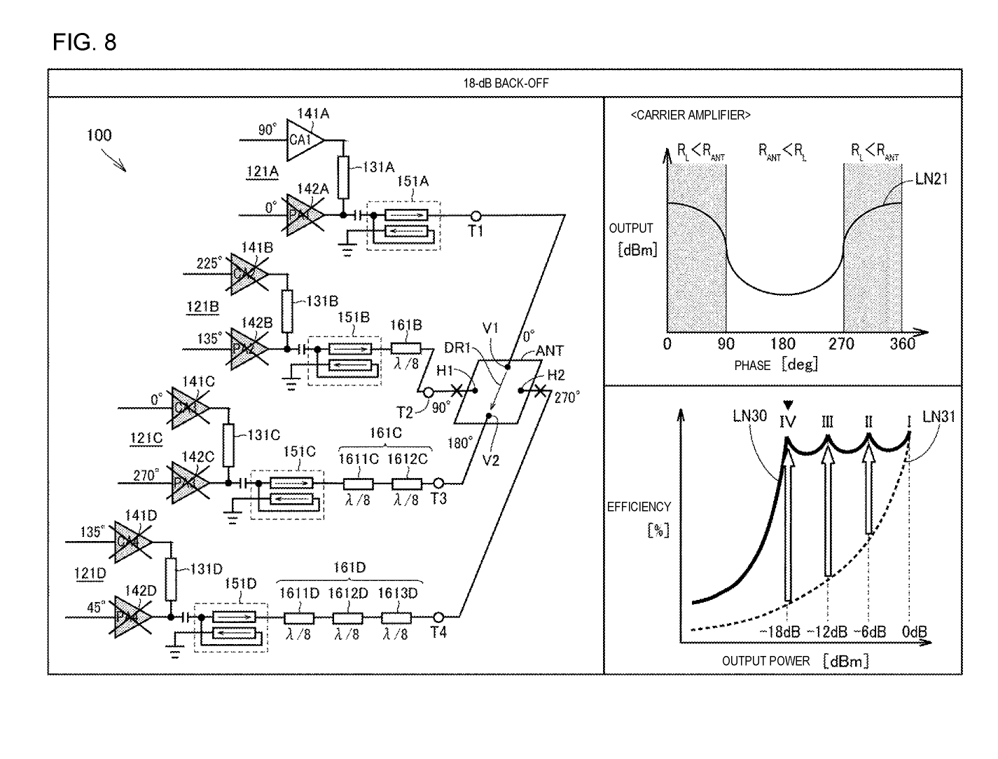

Next, FIG. 8 is used to describe an operation mode for the case of the fourth power value indicating a further lower power level. In this case, the power supply voltage Vcc is set to VC4.

In the operation mode (IV) in FIG. 8, the carrier amplifier 141C of the amplification circuit 121C is further deactivated in addition to the state in FIG. 7, and only the carrier amplifier 141A of the amplification circuit 121A is activated. In this case as well, only vertically polarized radio waves will be radiated.

In this case, due to the deactivation of the carrier amplifier 141C, the load impedance of the carrier amplifier 141A in operation is further doubled compared with the case in FIG. 7, and is eight times higher than in the case of maximum power. This increases the efficiency of the carrier amplifier 141A, resulting in an additional 6-dB back-off. Thus, an 18-dB back-off can be achieved in total.

Note that only one amplifier is activated in the operating state in FIG. 8, power variations in response to load variations can no longer be canceled out. However, the operation mode is applied to the operation region where output power is significantly small, and thus the occurrence of power variations in response to load variations does not result in significant losses. Therefore, it is not a practical problem.

As described above, in a transmission circuit that amplifies and transmits high-frequency signals to a radiating element having four feed points, by supplying high-frequency signals from Doherty amplifiers to the respective feed points and by arranging phase-shift lines that differ in length by λ/8 along lines from respective amplification circuits to the corresponding feed points, output power variations in response to load variations can be suppressed over the entire phase range, and the output power of at least one of the amplification circuits can be made higher than the average power. Thus, the robustness against load variations can therefore be further improved in the transmission circuit.

Furthermore, an 18-dB back-off can be achieved by switching the operating state of each amplifier in the amplifier circuit as appropriate in response to the power level of the output signal.

The feed point V1, the feed point H1, the feed point V2, and the feed point H2 according to the embodiment correspond to the first to fourth feed points according to the present disclosure, respectively. The amplification circuits 121A to 121D according to the embodiment correspond to first to fourth amplification circuits according to the present disclosure, respectively. The phase-shift lines 161B to 161D according to the embodiment correspond to the first to third phase-shift lines according to the present disclosure, respectively. Each of the phase-shift lines 131A to 131D according to the embodiment corresponds to a fourth phase-shift line according to the present disclosure. The balun 110 according to the embodiment corresponds to a second balun according to the present disclosure. The hybrid coupler 115A and the hybrid coupler 115B according to the embodiment correspond to a first hybrid coupler and a second hybrid coupler according to the present disclosure, respectively. The phase-shift line 116B, the phase-shift line 117D, the phase-shift line 117B, and the phase-shift line 116D according to the embodiment correspond to sixth to ninth phase-shift lines according to the present disclosure, respectively.

### Modification

In the power amplification circuit 100 according to the embodiment, the configuration has been described in which each amplification circuit is a current-combining Doherty amplifier. In a modification, the configuration will be described in which each amplification circuit is a voltage-combining Doherty amplifier.

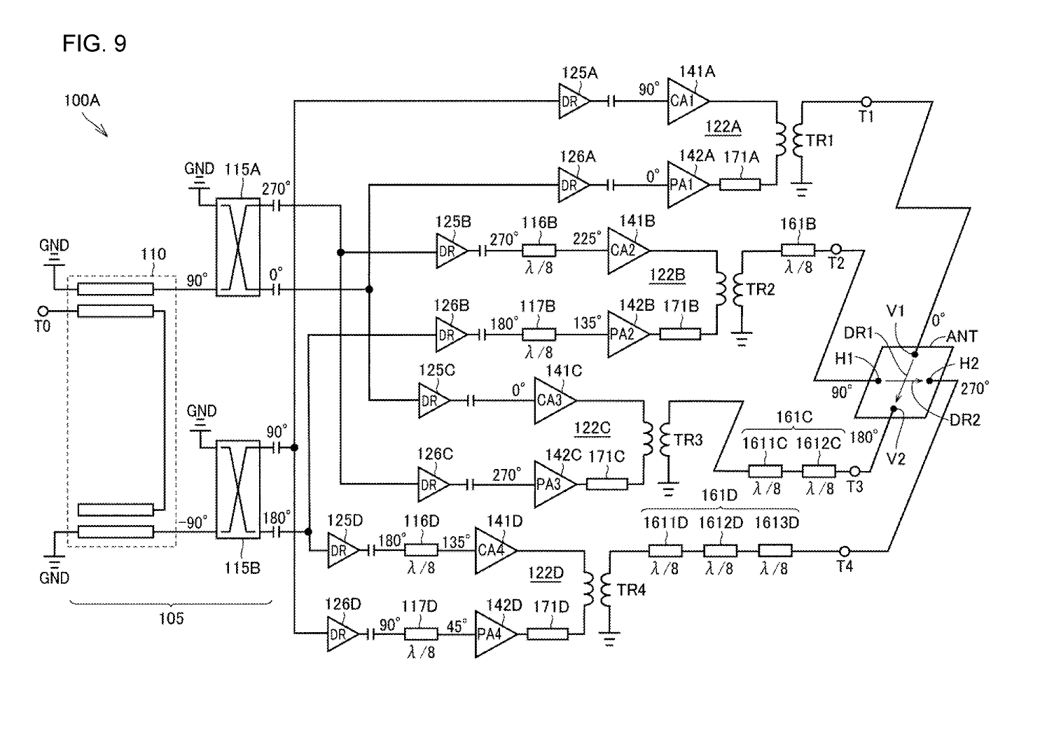

FIG. 9 illustrates the detailed configuration of a power amplification circuit 100A in a transmission circuit according to the modification. The power amplification circuit 100A has a configuration obtained by replacing the amplification circuits 121A to 121D in the power amplification circuit 100 with amplification circuits 122A to 122D. In the power amplification circuit 100A, the description of elements that are also included in the power amplification circuit 100 will not be repeated.

With reference to FIG. 9, each of the amplification circuits 122A to 122D in the power amplification circuit 100A is a voltage-combining Doherty amplifier that includes a carrier amplifier, a peaking amplifier, a phase-shift line having a line length of λ/4, and a balun. The balun is a transformer-type balun including primary and secondary windings.

More specifically, the amplification circuit 122A includes the carrier amplifier 141A, the peaking amplifier 142A, a phase-shift line 171A, and a balun TR1. The carrier amplifier 141A is connected to one end of the primary winding of the balun TR1. The peaking amplifier 142A is connected to the other end of the primary winding of the balun TR1 with the phase-shift line 171A interposed therebetween. One end of the secondary winding of the balun TR1 is connected to the feed point V1 of the radiating element ANT with the output terminal T1 interposed therebetween. The other end of the secondary winding of the balun TR1 is grounded.

The amplification circuit 122B includes the carrier amplifier 141B, the peaking amplifier 142B, a phase-shift line 171B, and a balun TR2. The carrier amplifier 141B is connected to one end of the primary winding of the balun TR2. The peaking amplifier 142B is connected to the other end of the primary winding of the balun TR2 with the phase-shift line 171B interposed therebetween. One end of the secondary winding of the balun TR2 is connected to the feed point H1 of the radiating element ANT with the phase-shift line 161B and the output terminal T2 interposed therebetween. The other end of the secondary winding of the balun TR2 is grounded.

The amplification circuit 122C includes the carrier amplifier 141C, the peaking amplifier 142C, a phase-shift line 171C, and a balun TR3. The carrier amplifier 141C is connected to one end of the primary winding of the balun TR3. The peaking amplifier 142C is connected to the other end of the primary winding of the balun TR3 with the phase-shift line 171C interposed therebetween. One end of the secondary winding of the balun TR3 is connected to the feed point V2 of the radiating element ANT with the phase-shift line 161C and the output terminal T3 interposed therebetween. The other end of the secondary winding of the balun TR3 is grounded.

The amplification circuit 122D includes the carrier amplifier 141D, the peaking amplifier 142D, a phase-shift line 171D, and a balun TR4. The carrier amplifier 141D is connected to one end of the primary winding of the balun TR4. The peaking amplifier 142D is connected to the other end of the primary winding of the balun TR4 with the phase-shift line 171D interposed therebetween. One end of the secondary winding of the balun TR4 is connected to the feed point H2 of the radiating element ANT with the phase-shift line 161D and the output terminal T4 interposed therebetween. The other end of the secondary winding of the balun TR4 is grounded.

With such a configuration, the four feed points of the radiating element ANT are supplied with signals that are phase-shifted by 90° in the rotational direction with respect to the center of the radiating element ANT, and the signals are combined at the radiating element ANT. As a result, for vertically polarized radio waves, power variations caused by load variations are canceled out by the signal supplied from the amplification circuit 122A and the signal supplied from the amplification circuit 122C. For horizontally polarized radio waves, power variations caused by load variations are canceled out by the signal supplied from the amplification circuit 122B and the signal supplied from the amplification circuit 122D. Thus, power variations in response to load variations can be suppressed over the entire phase range.

Furthermore, the phase-shift lines 161B, 161C, and 161D arranged at the output ends of the amplification circuits 122B to 122D, respectively, shift the phase at the output end of the amplification circuit 122B by 45°, that at the output end of the amplification circuit 122C by 90°, and that at the output end of the amplification circuit 122D by 135° with respect to the phase of the signal supplied to the radiating element ANT. This creates a 90° phase difference between the power variations of the signals supplied from the amplification circuits 122B and 122D and those of the signals supplied from the amplification circuits 122A and 122C in response to the load variations of the radiating element ANT. Thus, over the entire phase range, the output power of at least one of the amplification circuits can be made higher than the average power. The robustness against load variations can therefore be improved even in the communication device 1 equipped with the power amplification circuit 100A.

Furthermore, since each of the amplification circuits 122A to 122D is a Doherty amplifier, an 18-dB back-off can be achieved by switching the operating state of each amplifier in the amplifier circuit as appropriate in response to the power level of the output signal, as in the power amplification circuit 100 according to the embodiment.

The amplification circuits 122A to 122D according to the modification correspond to the first to fourth amplification circuits according to the present disclosure, respectively. Each of the phase-shift lines 171A to 171D according to the modification corresponds to a fifth phase-shift line according to the present disclosure. Each of the baluns TR1 to TR4 according to the modification corresponds to a first balun according to the present disclosure.

The embodiments disclosed herein should be considered illustrative and not restrictive in all aspects. The scope of the present disclosure is indicated by the claims, not by the above description of the embodiments, and is intended to include all changes within the claims and the meaning and scope of equivalents.

1. A transmission circuit that is configured to amplify and transmit high-frequency signals to a planar radiating element having a first feed point, a second feed point, a third feed point, and a fourth feed point, the transmission circuit comprising:
a first amplification circuit, a second amplification circuit, a third amplification circuit, and a fourth amplification circuit that are configured to supply high-frequency signals to the first feed point, the second feed point, the third feed point, and the fourth feed point, respectively;
a first phase-shift line connected between the second amplification circuit and the second feed point;
a second phase-shift line connected between the third amplification circuit and the third feed point; and
a third phase-shift line connected between the fourth amplification circuit and the fourth feed point,
wherein the first feed point and the third feed point are arranged at positions that are offset from a center of the radiating element in opposite directions from each other along a first direction,
wherein the second feed point and the fourth feed point are arranged at positions that are offset from the center of the radiating element in opposite directions from each other along a second direction that intersects the first direction,
wherein the first phase-shift line has a line length of λ/8, the second phase-shift line has a line length of λ/4, and the third phase-shift line has a line length of (3/8)λ, where λ is a wavelength of the high-frequency signals supplied to the radiating element.

2. The transmission circuit according to claim 1,
wherein the first direction and the second direction are orthogonal to each other,
wherein a high-frequency signal supplied to the second feed point is 90° ahead of a high-frequency signal supplied to the first feed point in phase,
wherein a high-frequency signal supplied to the third feed point is 90° ahead of the high-frequency signal supplied to the second feed point in phase, and
wherein a high-frequency signal supplied to the fourth feed point is 90° ahead of the high-frequency signal supplied to the third feed point in phase.

3. The transmission circuit according to claim 1,
wherein each of the first amplification circuit, the second amplification circuit, the third amplification circuit, and the fourth amplification circuit is a Doherty amplifier that comprises a carrier amplifier and a peaking amplifier, and
wherein, in each amplification circuit, the carrier amplifier is supplied with a signal that is 90° ahead of a high-frequency signal supplied to the peaking amplifier in phase.

4. The transmission circuit according to claim 3, wherein in a case where a power level of a high-frequency signal outputted from the radiating element has a first power value, the carrier amplifier and peaking amplifier of each amplification circuit are activated.

5. The transmission circuit according to claim 4, wherein in a case where the power level of the high-frequency signal outputted from the radiating element has a second power value that is smaller than the first power value:
the carrier amplifier of each amplification circuit is activated, and
the peaking amplifier of each amplification circuit is deactivated.

6. The transmission circuit according to claim 5, wherein in a case where the power level of the high-frequency signal outputted from the radiating element has a third power value that is smaller than the second power value:
for the first amplification circuit and the third amplification circuit, the carrier amplifiers are activated, and the peaking amplifiers are deactivated, and
for the second amplification circuit and the fourth amplification circuit, both the carrier amplifiers and the peaking amplifiers are deactivated.

7. The transmission circuit according to claim 6, wherein in a case where the power level of the high-frequency signal outputted from the radiating element has a fourth power value that is smaller than the third power value:
for the first amplification circuit, the carrier amplifier is activated, and the peaking amplifier is deactivated, and
for the second amplification circuit, the third amplification circuit, and the fourth amplification circuit, both the carrier amplifiers and the peaking amplifiers are deactivated.

8. The transmission circuit according to claim 3, wherein each of the first amplification circuit, the second amplification circuit, the third amplification circuit, and the fourth amplification circuit further comprises:
a fourth phase-shift line connected between an output end of the carrier amplifier and an output end of the peaking amplifier, and having a line length of λ/4; and
an impedance transformer connected to the output end of the peaking amplifier.

9. The transmission circuit according to claim 3,
wherein each of the first amplification circuit, the second amplification circuit, the third amplification circuit, and the fourth amplification circuit further comprises:
a fifth phase-shift line having a line length of λ/4; and
a first balun comprising an unbalanced terminal, a first balanced terminal, and a second balanced terminal,
wherein an output end of the carrier amplifier is connected to the first balanced terminal of the first balun, and
wherein a first end of the fifth phase-shift line is connected to the second balanced terminal of the first balun, and a second end of the fifth phase-shift line is connected to an output end of the peaking amplifier.

10. The transmission circuit according to claim 3, further comprising:
an input terminal;
a second balun comprising an unbalanced terminal, a first balanced terminal, and a second balanced terminal, the unbalanced terminal being connected to the input terminal;
a first hybrid coupler that has a first output terminal and a second output terminal and that is configured to output, from the first output terminal and the second output terminal, a signal from the first balanced terminal of the second balun; and
a second hybrid coupler that has a third output terminal and a fourth output terminal and that is configured to output, from the third output terminal and the fourth output terminal, a signal from the second balanced terminal of the second balun,
wherein the signal outputted from the first output terminal is supplied to the carrier amplifier of the second amplification circuit via a sixth phase-shift line having a line length of λ/8, and also supplied to the peaking amplifier of the third amplification circuit,
wherein the signal outputted from the second output terminal is connected to the peaking amplifier of the first amplification circuit, and also connected to the carrier amplifier of the third amplification circuit,
wherein the signal outputted from the third output terminal is connected to the carrier amplifier of the first amplification circuit, and also connected to the peaking amplifier of the fourth amplification circuit with a seventh phase-shift line having a line length of λ/8 interposed therebetween, and
wherein the signal outputted from the fourth output terminal is supplied to the peaking amplifier of the second amplification circuit via an eighth phase-shift line having a line length of λ/8, and also connected to the carrier amplifier of the fourth amplification circuit with a ninth phase-shift line having a line length of λ/8 interposed therebetween.

11. A communication device comprising:
the transmission circuit according to claim 1;
a signal processing circuit configured to process a high-frequency signal to be supplied to the transmission circuit; and
the radiating element configured to radiate a high-frequency signal amplified by the transmission circuit as radio waves.
